(19) United States
(12) Patent Application Publication
(10) Pub. No.: US 2024/0085242 A1
(43) Pub. Date: Mar. 14, 2024

(54) METHOD OF DETERMINING ACCURACY OF A CALIBRATION OF A RADIOMETER

(71) Applicant: GEORGE BROST, LEE CENTER, NY (US)

(72) Inventor: GEORGE BROST, LEE CENTER, NY (US)

(21) Appl. No.: 17/125,548

(22) Filed: Dec. 17, 2020

(51) Int. Cl. G01J 5/80; G01J 5/53

(52) U.S. Cl. CPC G01J 5/804; G01J 5/53

(57) ABSTRACT

The invention discloses a method which analyzes regression coefficient and spectral consistency in the determination of the accuracy of a calibration for a radiometer. The invention's method simulates the output of a total power radiometer and quantifies the calibration accuracy under various atmospheric conditions.

Pursuant to 37 C.F.R. § 1.78(a)(4), this application claims the benefit of and priority to prior filed co-pending Provisional Application Ser. No. 61/949,510, internally referenced RLP1132, filed Dec. 18, 2019, which is expressly incorporated herein by reference.

### RIGHTS OF THE GOVERNMENT

The invention described herein may be manufactured and used by or for the Government of the United States for all governmental purposes without the payment of any royalty.

### FIELD OF THE INVENTION

The present invention relates generally to ground-based radiometer calibration and, more particularly, to improvements in accuracy thereof.

### BACKGROUND OF THE INVENTION

The tipping-curve method is widely used in the prior art to provide the cold calibration point for calibration of ground-based radiometers. It is generally considered to be highly accurate. Uncertainties of less than 0.5 K have been reported. The prior art method assumes a horizontally stratified atmosphere in which the opacity is proportional to the air mass. Statistical analysis of the opacity air mass pairs, including the linear regression coefficient (r), the standard deviation of the equivalent zenith brightness temperature EZTb (σ_{z}) and x² have also generally been used in the prior art as a measure of the tip curve quality. Many users have established acceptance criteria to ensure the quality of the calibration. For example, values for the regression coefficient reported in the previous literature have ranged from r=0.99 to r=0.9999. Küchler et. al (“Calibrating ground-based microwave radiometers: uncertainty and drifts”, Radio Sci., 51, 311-327, doi:10.1002/2015RS005826) proposed the use of spectral consistency as an alternative quality check to the usual statistical analysis. The choice of the criteria threshold has to date been somewhat subjective. Further, to date there has not been an analysis that has related the acceptance criteria to the calibration accuracy.

### SUMMARY OF THE INVENTION

The present invention overcomes the foregoing problems and other shortcomings, drawbacks, and challenges of accurate calibration of ground-based radiometers. While the invention will be described in connection with certain embodiments, it will be understood that the invention is not limited to these embodiments. To the contrary, this invention includes all alternatives, modifications, and equivalents as may be included within the spirit and scope of the present invention.

According to one embodiment of the present invention a method of determining an accuracy of a calibration for a radiometer is disclosed. The method includes simulating a tipping curve calibration; analyzing a variation in a frequency and in atmospheric model opacity characteristics; calculating a brightness temperature via a radiative transfer analysis; determining a corresponding voltage for an air mass; determining an initial value for a calibration parameter a and a calibration parameter b using an ambient calibration and an estimate of a zenith brightness temperature; calculating a tipping curve opacity from an estimated calibration parameter and a voltage measurement; adjusting a calibration parameter by changing the value of calibration parameter a and calibration parameter b until an absolute value of calibration parameter b is less than a value of an epsilon; and determining an acceptance criteria of epsilon.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The accompanying drawings, which are incorporated in and constitute a part of this specification, illustrate embodiments of the present invention and, together with a general description of the invention given above, and the detailed description of the embodiments given below, explain the principles of the present invention.

FIG. 1A is a graphical representation of data presenting RMS error (K) in view of Regression Coefficient with 5%, 10% 20% and slope indicated above the relative occurrences as plotted against the regression coefficient in the same scale for each of 5%, 10% and 20%;

FIG. 1B is a graphical representation of data presenting Relative Occurrence in view of Regression Coefficient at each of 5%, 10%, and 20%;

FIG. 2 is a graphical representation of data presenting RMS error (K) in view of Regression Coefficient showing RMS error and Distribution results overlaying the Relative Occurrence;

FIG. 3 is a graphical representation of data presenting RMS error (K) against the Regression Coefficient for 1-sided and 2-sided TCCs with random perturbations;

FIG. 4 is a graphical representation of data presenting the standard deviation (K) against the Regression Coefficient for the 22.24 GHz channel indicating spectral consistency;

FIG. 5 is a graphical representation of data presenting Absolute Error (K) against Standard Deviation (K) indicating spectral consistency for measurement of the 79 K black body target;

FIG. 6 is a table of data indicating slope values of error versus spectral consistency standard deviation for different surface water vapor concentrations indicating Frequency in GHz with results for each of 5, 10 and 15 g/m3; and

FIG. 7 is a graphical representation of absolute error versus spectral consistency standard deviation of measurement of 79 K and 400 K black body targets.

FIG. 8 is a representation of method steps for determining an accuracy of a calibration of a radiometer.

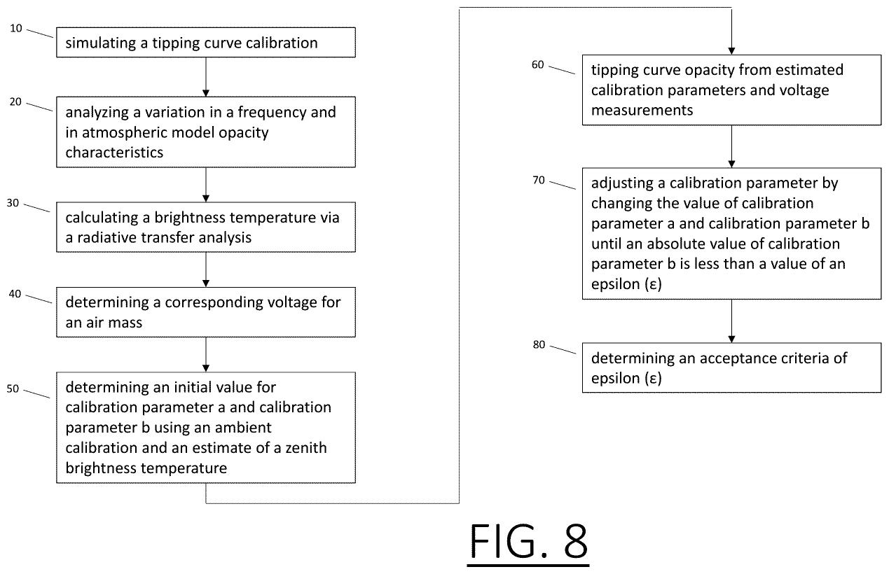

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION OF THE INVENTION

The following examples illustrate particular properties and advantages of some of the embodiments of the present invention. Furthermore, these are examples of reduction to practice of the present invention and confirmation that the principles described in the present invention are therefore valid but should not be construed as in any way limiting the scope of the invention.

To address this unmet need, the present invention discloses a method which analyzes regression coefficient and spectral consistency in the determination of the accuracy of a calibration for a radiometer. The invention's method simulates the output of a total power radiometer and quantifies the calibration accuracy under various atmospheric conditions. Horizontal inhomogeneity is generated by adding random perturbations to the water vapor content of model atmospheres. A two-point calibration scheme with an ambient target is used to couple the radiometer equation with the tipping curve measurements to derive the calibration constants. The invention's method considers the error between the true zenith brightness temperature and the calibrated zenith brightness temperature.

The tipping curve method of calibration as applied to a total power radiometer is as follows. First generally on radiometer calibration, followed by the tipping curve method itself. The two-point radiometer calibration determines the relation between the detected voltage (V) and the received power from black body targets of known physical temperature (T). For a square law detector the radiometer equation which gives the relation between the measured brightness temperature (Tb) and voltage (V) is given by

Tb=a·V+b (1)
where a and b are the calibration parameters. The two calibration temperatures are typically chosen to be an ambient target for the hot temperature T_{H} and a cold temperature T_{C}. The tipping curve method estimates the zenith brightness temperature for the cold temperature.

### Tipping Curve Method

The tipping curve method utilizes the linear dependence of opacity (τ) on normalized air mass (m) for a horizontally stratified atmosphere:

τ=A·m+B (2)

In this method brightness temperature is measured with estimated values of a and b for a variety of air masses (i.e. elevation angles) and the opacity is determined by

$$τ = ln [ \frac{Tmr - {T}_{0}}{Tmr - Tb} ] , \qquad ( 3 )$$

where Tₘᵣ is the mean radiating temperature and T₀ is the effective cosmic background temperature. In the conventional tipping curve method intercept B of the linear fit to the data is expected to be zero when properly calibrated. The calibration parameters a and b, which are coupled by the ambient target calibration, are adjusted until B=0. Then slope A is equal to the zenith opacity. The zenith brightness temperature T_{Z}, determined by inversion of equation (3) is then the cold calibration temperature. Alternatively, new values of a and b from the fitting process are used as the final calibration parameters. Sources of errors in calibration, and ways to eliminate or minimize them are discussed in [1].

### Tipping Curve Analysis

### Methodology

In a tipping curve analysis the atmospheric conditions are derived from model atmospheres in ITU-R P.835-6 in which the water vapor content of each air mass ρ(m) is modified with a random perturbation Δρ(m) to induce atmospheric inhomogeneity. Tipping curve calibrations are simulated 10 for typically used K-band frequencies. Variation in frequency and atmospheric model provides analysis 20 for different opacity characteristics. Brightness temperatures are calculated 30 through radiative transfer analysis. Values for the true calibration parameters are defined and the corresponding voltage for each air mass are determined 40 by inversion of equation (1). Initial values for the calibration parameters a and b are determined 50 by the ambient calibration at TA=300 K and an “estimate” of the zenith brightness temperature. In clear weather it is quite possible to estimate the zenith brightness temperature to within a few percent RMS error. The true zenith brightness temperature is changed by a few degrees for the “estimate” so that the radiometer is initially mis-calibrated. Tipping curve opacities were then calculated 60 from the estimated calibration parameters and the voltage measurements. The calibration parameters are adjusted 70 by changing the value of a (and consequently b) until |B|<ε. The choice 80 of ε is an acceptance criteria. For example, a value of ε=0.001 Nepers is used. This is based on the uncertainty in the intercept. Experimentation with smaller values of ε do not appear to provide any significant difference in the results. Usually only one or two iterations of the method are required. Unless otherwise stated, the method assumes other sources of error to be zero.

The calibration from the tipping curve procedure may be realized in different ways. The most common is to use the slope of the linear regression as the zenith opacity to find the cold temperature. Similar results are obtained by using the mean equivalent zenith opacity. Some users have used the updated calibration parameters from the tipping curve. An analysis of the present invention's method showed that this approach gave slightly RMS error than the other two methods. Results below refer to the slope method.

Multiple tipping curve simulations were conducted to provide the error between the true and the calibration zenith brightness temperature as a function of acceptance criteria parameters. The results reported below are for air masses [1, 1.5, 2, 2.5, 3] denoted as m1, set of 10 air masses, m2, corresponding to both sides of the radiometer, and a set of 10 air masses [1,1.15,1.25,1.5,1.75,2,2.25,2.5,2.75,3].

### Results

Regression analysis

It was supposed that if the regression analysis was an accurate measure of the tipping curve quality then the relationship between the RMS error and regression coefficient would be independent of how the perturbation of the water vapor content was applied. In this case uncertainty in the retrieved TZ would be expected to be related to the standard deviation of the slope (σA):

ΔT_Z=(T_mr-T_0)e\hat{ }(−A)σ_A. (4)

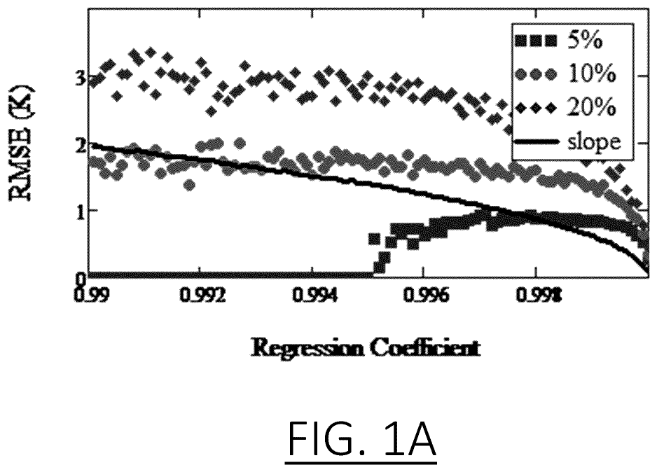

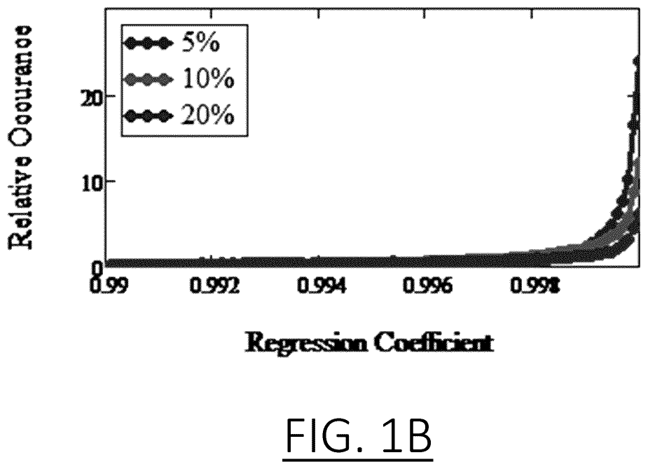

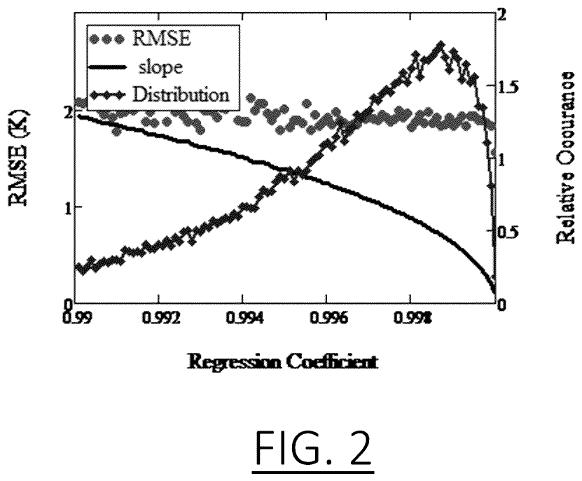

However, this turned out to not be the case. The RMS error did not match the uncertainty in the in the zenith brightness temperature as seen in FIGS. 1A and 2. The RMS error characteristics depended on the nature of the water vapor perturbation. In FIG. 1A Δρ(m) for each TCC was a random value between −Δρn and Δρn, where Δρn was a random value between 0 and Δρmax. Here Δρmax was a percentage of the unperturbed water vapor content ρ0. . The relative occurrence for each set of curves is shown in (b). The magnitude of the error scaled with magnitude of the perturbation, and large errors could occur even at high regression coefficient, although with low probability. In FIG. 2 Δρ(m) was a random value from a normal distribution with a standard deviation=to 0.05·ρ0 The ΔTzenith dependence on regression coefficient did not depend on the perturbation.

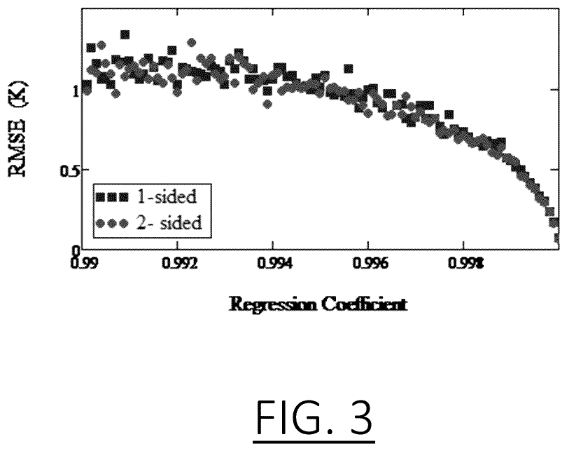

The results in FIGS. 1A and 2 were for 23.8 GHz with surface water vapor concentration of ρ0=7.5 gm/m3 and exponential scale height of 2.km with five air masses (m1). FIG. 3 shows results comparing one-sided and two-sided TCCs with 10 air masses.

Regarding FIG. 1A: TCC results for different values of Δρmax given as a percentage of ρ0. The black line is the uncertainty from the standard deviation of the slope. The bottom curve is the relative occurrences.

Regarding FIG. 2: TCC results for Δρ(m) from random value with Gaussian distribution with zero mean and 5% standard deviation. The black line is the uncertainty for the standard deviation of the slope.

Regarding FIG. 3: Results comparing 1-sided and 2-sided TCCs with random perturbations.

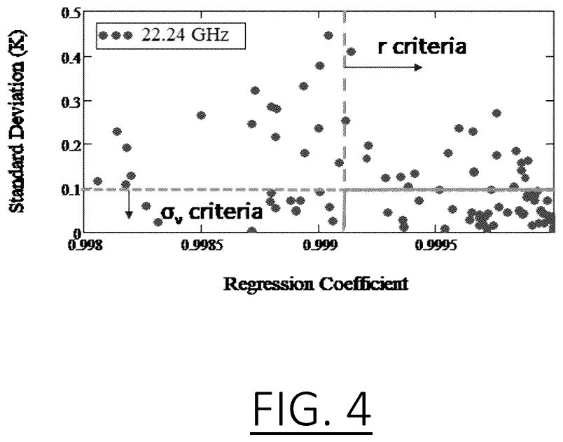

Regarding FIG. 4: Scatter plot of spectral consistency standard deviation versus regression coefficient of the 22.24 GHz channel.

### (2) Spectral Consistency

Küchler et. al [2] proposed the use of spectral consistency as an alternative quality check. In their microwave radiometer calibration study both tipping curve and liquid nitrogen calibrations were performed. There spectral consistency was measured by the standard deviation of the seven K-band channel measurements of the liquid nitrogen target brightness temperature (σv). They suggested a criterion of the standard deviation equal to the radiometric resolution of 0.1 K. It was also noted that many tipping curve calibrations that passed the regression criterion (0.9991) did not pass the spectral consistency criterion and vice versa.

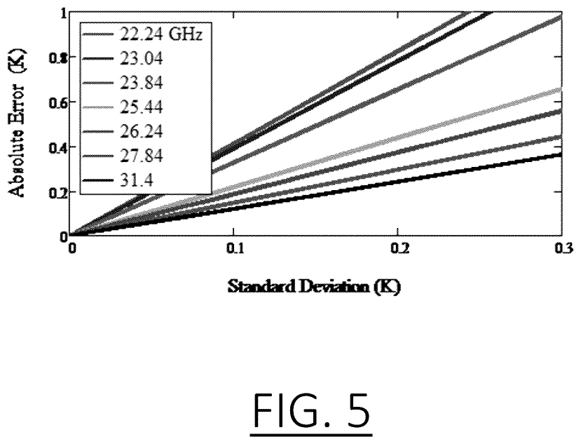

The experimental conditions of Küchler et. al [2] were simulated. FIG. 4 shows a scatter plot of the standard deviation as a function of linear regression coefficient for the 22.4 GHz channel. This result is consistent with the observations in [2] that the two criterion did not match well. FIG. 5 shows a plot of the absolute error as a function of the standard deviation. It is seen that absolute error varied linearly with standard deviation and the magnitude increased with water vapor opacity. The slopes of the curves were weakly dependent on total opacity as seen in Table 1. In contrast to the regression coefficient results, these were well-defined relationships that did not depend on how the perturbations were applied.

Regarding FIG. 5: Absolute error versus spectral consistency standard deviation of measurement of the 79 K black body target.

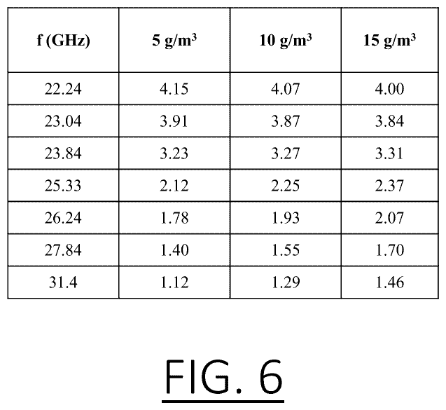

Regarding FIG. 6: Slope values of error versus spectral consistency standard deviation for different surface water vapor concentrations.

It was not possible to establish a definite relation between the RMS error and the regression coefficient. While the random perturbations may be possible occurrences, natural variations in water vapor field are insufficiently known to draw those conclusions. RMS errors were greater than that expected from the slope uncertainty at high regression coefficients. This is likely due to net horizontal gradients in water vapor content. Gradients have the effect of changing the slope but not the linearity. Small gradients on the order of 1 or 2% per unit air mass can result in noticeable errors. Two-sided TCCs which use both sides of the radiometer eliminated errors due to a uniform horizontal gradient. Yet the RMS errors were similar for one-sided and two-sided TCCs when random perturbations were applied.

On the other hand, the spectral consistency standard deviation was found to be a robust measure of tipping curve accuracy. This robustness was due in largely to each channel seeing the same atmosphere and consequently the calibration errors were correlated. Also, the calibration error scaled with opacity. Subsequently the error had a well-defined dependence on the standard deviation. Knowledge of this dependence offers the possibility to also improve the TCC calibration with an adaptive algorithm.

The linear regression coefficient has been used as a measure of the tipping curve quality. However, the results of the analysis here showed that a high linear regression coefficient did not ensure an accurate calibration. While tipping curve calibrations are capable of providing high accurate estimates of the zenith brightness temperature, it cannot be assumed that all tipping curve calibrations provide that level of accuracy.

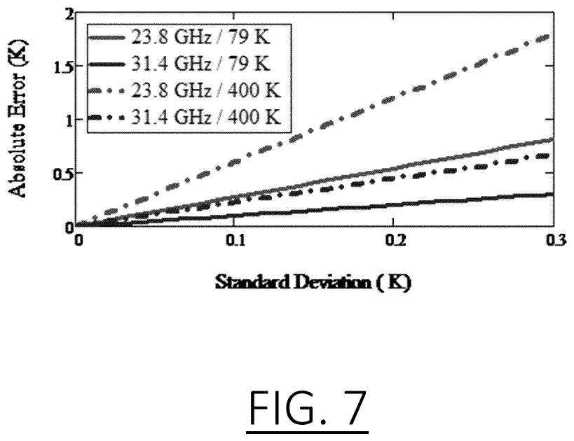

In one example elucidated in Küchler et. al [2] a liquid nitrogen cooled target was used as the reference black body. A more convenient implementation could be achieved with a matched load placed at the radiometer input. The essential requirement is that Tref should be somewhat different than TZ and TA, and need not be known to calculate the standard deviation. The sensitivity of the method is dependent on Tref. This is shown in FIG. 7 which compares the results for reference temperatures of 79 K and 400 K for the case of two channels at 23.8 GHz and 31.4 GHz.

Regarding FIG. 7: Absolute error versus spectral consistency standard deviation of measurement of 79 and 400 K black body targets.

It may be noted that the tipping curve of a calibrated radiometer does not necessarily pass through the origin in a non-stratified atmosphere. The reason is that the air mass values are not correct. Adjusting the calibration parameters does not affect the air mass values. It was observed that adjusting the calibration parameters had little effect on the slope. However, that adjustment did affect the calibration that used these parameters rather than the slope.

Tipping curve calibration acceptance criteria were analyzed by simulating the radiometer measurements with random perturbations of water vapor. It was not possible to establish a well-defined relation between the RMS error and the regression coefficient, as it depends on the unknown natural variation in water vapor content. A high linear regression coefficient did not ensure an accurate calibration, likely due to net gradients. On the other hand, standard deviation of brightness temperature measurements of a reference black body (spectral consistency) provided a robust measure of the calibration error. This capability could readily be implemented in the design of a radiometer.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. A method of determining an accuracy of a calibration for a radiometer, comprising:
simulating a tipping curve calibration;
analyzing a variation in a frequency and in atmospheric model opacity characteristics;
calculating a brightness temperature via a radiative transfer analysis;
determining a corresponding voltage for an air mass;
determining an initial value for a calibration parameter “a” and a calibration parameter “b” using an ambient calibration and an estimate of a zenith brightness temperature;
calculating a tipping curve opacity from an estimated calibration parameter and a voltage measurement;
adjusting a calibration parameter by changing the value of calibration parameter “a” and calibration parameter “b” until an absolute value of calibration parameter “b” is less than a value of an epsilon ε; and
determining an acceptance criterion of epsilon ε.

2. The method of claim 1, wherein said step of determining a brightness temperature via a radiative transfer analysis further comprises the step of computing the inversion of
Tb=a·V+b
where
Tb is a measured brightness temperature
V is a detected voltage
a is a calibration parameter
b is a calibration parameter

3. The method claim 1 wherein said frequency is in the K-band range of frequencies.

4. The method of claim 1, wherein said ambient calibration is performed at 300K.

5. The method of claim 1, wherein said opacity is determined by computing
$$τ = LN [ \frac{Tmr - {T}_{0}}{Tmr - T b} ]$$
where
τ is opacity
Tmr is a mean radiating temperature
T₀ is an effective cosmic background temperature
Tb is a measured brightness temperature

6. The method of claim 1, wherein said zenith brightness temperature Tz is determined by computing the inverse of
$$τ = LN [ \frac{Tmr - {T}_{0}}{Tmr - T b} ]$$
where
τ is opacity
Tmr is a mean radiating temperature
T₀ is an effective cosmic background temperature
Tb is a measured brightness temperature

7. The method of claim 6, wherein said zenith brightness temperature Tz is used as a cold calibration temperature.

8. The method of claim 1, wherein said estimate of a zenith brightness temperature comprises a true zenith brightness temperature altered so as to initially mis-calibrate said radiometer.

9. The method of claim 1, wherein said acceptance criteria for epsilon ε is 0.001 Nepers

10. The method of claim 1, further comprising using the slope of a linear regression as a zenith opacity to find a cold temperature.

11. The method of claim 1, further comprising using a mean equivalent zenith opacity to find a cold temperature.

12. The method of claim 1, further comprising calculating an error between the true and the calibration zenith brightness temperature as a function of acceptance criteria parameters.
